(19) United States
(12) Patent Application Publication
(10) Pub. No.: US 2009/0014840 A1
(43) Pub. Date: Jan. 15, 2009

(54) Method for the production of crystalline silicon foils

(75) Inventor: Axel Georg Schonecker, Alkmaar (NL)

Correspondence Address: THE WEBB LAW FIRM, P.C., 700 KOPPERS BUILDING, 436 SEVENTH AVENUE, PITTSBURGH, PA, 15219, US

(73) Assignee: RGS DEVELOPMENT B.V., Petten (NL)

(21) Appl. No.: 11/628,913

(22) PCT Filed: Jun. 10, 2005
(86) PCT No.: PCT/NL2005/000422

§ 371 Date: Apr. 1, 2008

(30) Foreign Application Priority Data
Jun. 10, 2004 (NL) 1026377

(51) Int. Cl. C30B 1/00; H01L 21/00; H01L 29/00

(52) U.S. Cl. 257/618; 438/499; 117/10; 257/E21.211; 257/E29.001

(57) ABSTRACT

The invention is a method for the production of a silicon foil with a targeted charge carrier transport to the p-n transition by means of an integral electric field (‘drift field’). By varying the crystal growth speed and introducing a doping substance into the fluid silicon beforehand, a crystallization process can be carried out in such a way that a gradient over the foil thickness is produced in the doping profile in the silicon. This gradient of the doping profile gives rise to an electric field. With the aid of various foil casting techniques foils that are suitable for the production of solar cells can thus be produced in a relatively simple manner.

The invention relates to a method for the production of crystalline semiconductor foils with an integrated electric field, comprising drawing a foil from a melting crucible of fluid semiconductor.

Such a method is known per se. After the foil has been drawn the foil is divided into pieces. These pieces are then exposed to a diffusion process in which a doping substance is diffused into the foil. The method is suitable in particular for the production of rectangular solar cells that can easily be assembled to give solar panels. Here crystalline is understood to be both polycrystalline and monocrystalline material.

Solar cells consist of light-absorbent foil consisting of a semiconductor with an integral transition from a p-conducting to an n-conducting region therein. The principle of solar cells is that photons that have more energy than the energy between the conduction and valence band of the semiconductor generate charge carrier pairs (that is to say hole-electron pairs) when they are absorbed in the semiconductor material. The charge carriers diffuse through the semiconductor foil until they either traverse the p-n transition or recombine with a second charge carrier. If they have passed the p-n transition the charge carriers can supply electric power to an external electrical load. The efficiency of a solar cell is reduced by the recombination of charge carriers in a solar cell, where the separation energy of a charge carrier pair is converted back into heat and is not available as electrical energy. The efficiency of a solar cell is to a significant extent determined by the life of the charge carriers (that is to say the time between generation and recombination). If this life is long, it is then more probable that a charge carrier reaches the pn transition and contributes to the electric power.

In advanced solar cells the life of the charge carriers is very long. To a large extent all holes and electrons that are created by incident photons have sufficient time to diffuse to the other side of the transition and thus contribute to the power of the cell. However, the life of the charge carriers is based on physical properties of the semiconductor. Impurities in the material can add additional recombination sites, as a result of which the life will shorten. If the life of minority charge carriers decreases, more holes and electrons will recombine and disappear before they are able to make a contribution to the power of the cell. This gives rise to a poorer efficiency of the cell. One method for increasing this efficiency is to direct the incidental diffusion of the charge carrier towards the p-n transition in such a way that the likelihood of reaching the p-n transition within the life of the charge carrier is appreciably increased. This can be achieved by applying a drift field in the foil, as a result of which charge carriers are transported explicitly towards the pn transition (drift current) instead of diffusing incidentally. These solar cells are also termed drift cells. By applying a drift field the transport of charge carriers towards the pn transition is increased so that minority charge carriers that are generated relatively far away from the pn transition by incident solar radiation will also transverse the pn transition.

One option for producing such ‘drift cells’ is molecular beam epitaxy (MBE) in order to make cells with an increasing n+−n doping in order to create a strong drift field. Making drift cells by means of MBE is very expensive because of the method used. Another method is to diffuse doping substances at a high temperature into crystalline foils that have already been produced. Because of the low diffusion coefficient of the conventional doping substances this method is very slow and thus also relatively expensive.

In the publication by Bell R. O. et al.: “Effect of doping gradients on solar cell efficiency”, Photovoltaic specialists conference, Las Vegas, Oct. 21-25, 1985 New York, IEEE, US, part VOL. 1 CONF. 18, 21 Oct. 1985, pages 764-769 a study is described in which use was made of an edge-defined foil-fed growth (EFG) film drawing technique. The publication describes the possibility of obtaining a desired distribution of the doping in a crystallised (hollow tubular) foil with the aid of the correct doping substance concentration in the fluid silicon and a correct growth rate. In the case of EFG, crystallisation of the silicon proceeds inwards from two outer surfaces, the innermost portion of the foil remaining fluid for longest in the growth region. By means of segregation the concentration of doping substance in the fluid silicon is increased just in front of a crystallisation front. By inclusion of fluid silicon with a higher concentration between the two crystallisation fronts, maximum doping is obtained in the middle of the foil. With this method a crystallisation front has a horizontal growth rate component that is constant because the heat of crystallisation is dissipated by radiation. This component is so small that the effective segregation coefficient for a doping substance is equal to the equilibrium segregation coefficient. A consequence of this, which has already been mentioned, is accumulation of the doping substance in front of the crystallisation fronts.

Another method is described in the publication by McCann M. J. et al.: “Boron doping of silicon layers grown by liquid phase epitaxy”, Journal of crystal growth, North-Holland Publishing co. Amsterdam, NL, part 241, no. 1-2, May 2002 pp. 45-50, where a liquid phase epitaxy (LPE) growth method is used and the active doping substance concentration in the melting crucible during the process is lowered by means of cluster formation of the doping substance (boron). As a result a specific doping profile is produced in the crystallised silicon layer.

One aim of the present invention is to provide an alternative for the production of crystalline semiconductor layers with integral electric field.

Said aim is achieved by a method as described in the preamble, characterised by:

doping the fluid semiconductor with a doping substance having an equilibrium segregation coefficient k₀ where k₀<<1,

wherein a crystallisation rate varies in a direction essentially perpendicular to the production direction of the foil during film drawing.

Because the crystal growth rate varies and a doping substance with a suitable segregation coefficient is used, a doping gradient is obtained that is responsible for an integral drift field.

Preferably the heat of crystallisation is dissipated so rapidly that an initial crystal growth rate is so high that the effective segregation coefficient k_{eff} is virtually equal to 1. As a result a doping profile can be created that has a desired high value on one side of the foil. This provides a drift field that is highly desirable in, for example, solar cells.

The semiconductor is preferably silicon. This semiconductor is, inter alia, very suitable for the production of solar cells. In order to enable the fluid silicon to crystallise it can, for example, be brought into contact with a substrate or with a grating, which have a lower temperature than that of the fluid silicon. Possible techniques that can be used for this are RGS (Ribbon Growth on Substrate), S-Web technique, see, for example, U.S. Pat. No. 4,554,203, SSP (Silicon Sheets from Powder), see, for example, U.S. Pat. No. 4,690,797. In all these techniques a foil is drawn where the crystal growth rate is perpendicular, or virtually perpendicular, to the production direction of the foil.

An additional advantage of these techniques is that a thermal resistance in the crystallised foil increases as the growth process proceeds, as a result of which the growth rate of the crystal automatically decreases.

Nevertheless, it can be necessary to exert an additional influence on the dissipation of heat from the crystallisation process in order thus to achieve the correct effect. One option in the case of the use of a substrate band is to increase the substrate temperature dynamically, as a result of which the growth rate decreases. The same applies for techniques where a grating is used, such as in the case of S-web.

Preferably a doping substance is used which has an equilibrium segregation coefficient k₀ of less than 0.01. It has been found that very good results are obtained making use of gallium (k₀=0.008) as doping substance in the silicon.

Further advantages and characteristics of the present invention will become apparent on the basis of a description of a few embodiments, where reference is made to the appended drawings, in which:

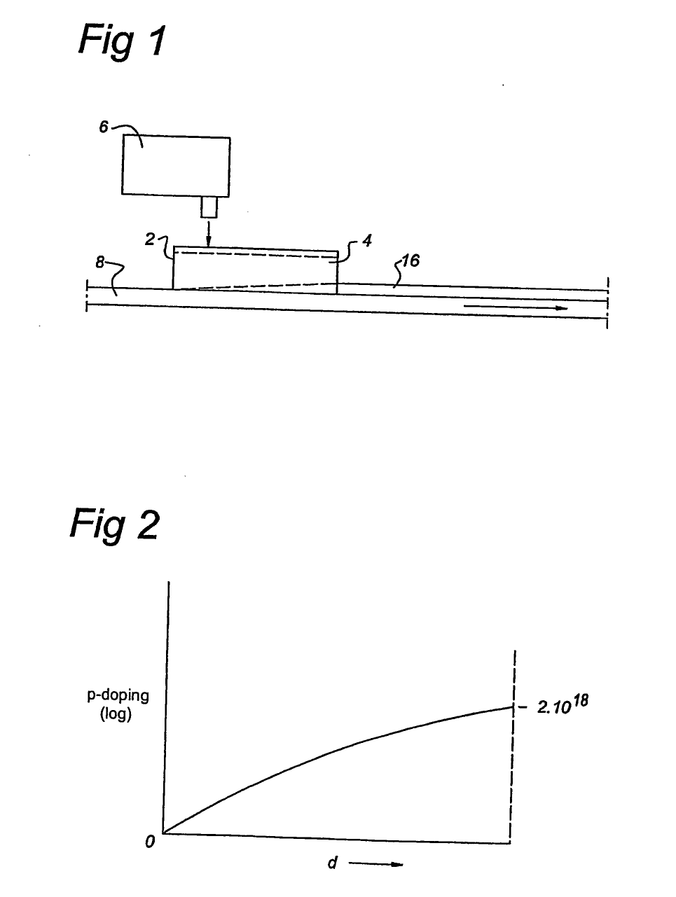

FIG. 1 is a diagrammatic side view of a foil casting device;

FIG. 2 is an example of the doping profile of a foil produced using the method according to the invention;

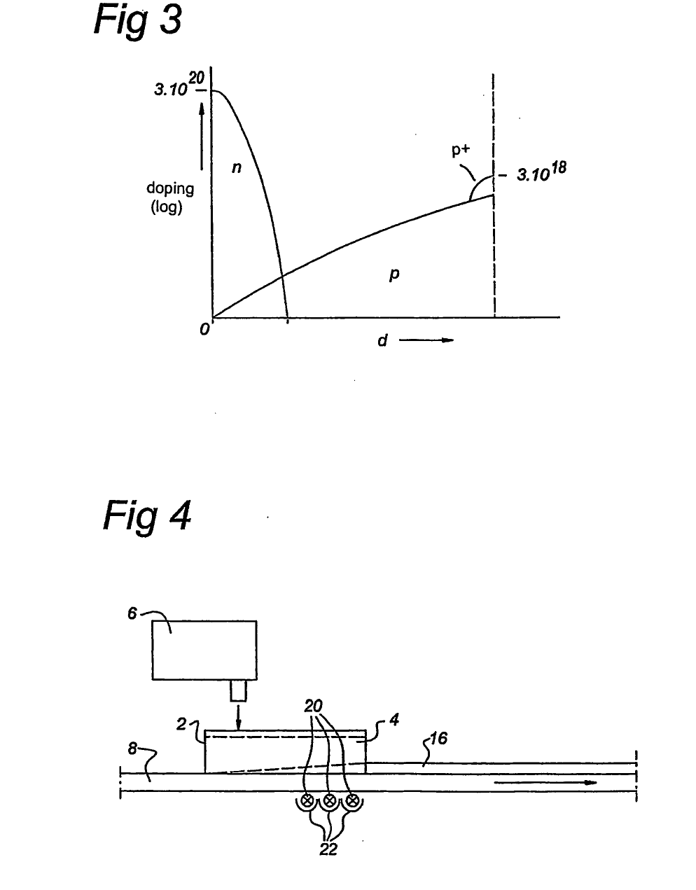

FIG. 3 is an example of the doping profile of the foil in FIG. 2, where two additional diffusion steps are carried out;

FIG. 4 is a side view of a foil casting device where the crystal growth rate is actively influenced by means of a halogen lamp.

FIG. 1 shows a diagrammatic side view of a foil casting device 1 with which a preferred embodiment of the present invention can be carried out. The device 1 consists of a casting frame 2 into which fluid silicon can be poured. The fluid silicon 4 is poured into the casting frame 2 with the aid of a feed device 6. Below the casting frame 2 there is a substrate band 8 that is set up to pass underneath the casting frame 2 at a specific speed. The drive installation required for this has not been drawn in FIG. 1. The temperature of the substrate band 8 is set such that the fluid silicon 4 crystallises at the surface with the substrate band 8. Because the substrate band 8 is moving, to the right in FIG. 1, a foil 16 will be produced on a downstream side of the casting frame 2. This foil 16 pushes the casting frame 2 upwards on the downstream side, as a result of which the casting frame tilts slightly. A foil is drawn in this way. The method described here is termed RGS (Ribbon Growth on Substrate). A major advantage of RGS is that a relatively large amount of foil can be produced per hour.

In the present invention the doping substance that produces an electric field is admixed into the fluid semiconductor. According to the present invention the semiconductor is doped with a doping substance that has a segregation coefficient k₀ that typically is less than 0.01. The segregation coefficient k₀ under equilibrium conditions, that is to say the equilibrium segregation coefficient, is defined as follows:

K₀=C^{s}₀/C^{L}₀ (1)

where C^{s}₀ is the solubility of the doping substance in the solid semiconductor and C^{L}₀ is the solubility in the fluid semiconductor at melt temperature.

The equilibrium segregation coefficient of boron in silicon is k₀=0.8. That is to say if the casting frame is filled with, for example, fluid silicon doped with boron, the boron prefers to be in the fluid silicon rather than in the solid silicon. However, the preference for boron to be in the fluid silicon is not extreme; after all, the equilibrium segregation coefficient is virtually equal to 1.0.

Crystallisations performed industrially typically take place at crystal growth rates that no longer can be regarded as equilibrium situations. In these cases the difference in the concentration of impurities in the fluid phase and solid phase respectively is no longer described by the equilibrium segregation coefficient. In these cases the difference in concentration is determined by the effective segregation coefficient, which is defined as follows:

k_{eff}=k₀/(k₀+(1−k₀)exp(−vδ/D)) (2)

where v is the rate of crystallisation and δ the thickness of the enrichment zone (that is produced because at the high rate of crystallisation insufficient time remains to distribute the raised impurity concentration in the fluid phase) in the fluid in front of the crystallisation front and D is the diffusion rate of the impurities (doping substance) in the fluid phase.

### Furthermore

k_{eff}=C^{S}_{eff}/C^{L}₀ (3)

where C^{S}_{eff} is the concentration of the doping substance achieved in the solid silicon and C^{L}₀ is the solubility in the fluid semiconductor at melt temperature.
It follows from equation 2 that if rate of crystallisation v is low the effective segregation coefficient k_{eff} approaches the equilibrium segregation coefficient k₀. At a high rate of crystallisation v the effective segregation coefficient k_{eff} approaches the value 1, which means that C^{S}_{eff}=C^{L}₀. That is to say the concentration achieved in the solid silicon is equal to the concentration in the fluid silicon irrespective of the value of k₀. If the rate of crystallisation is changed from high to low, the effective segregation coefficient k_{eff} will change from 1 to k₀.

This insight is used in the method according to the invention, in combination with a doping substance with a low segregation coefficient, in order to create a desired drift field. By making use of the foil casting principle, a varying rate of crystallisation v is achieved. With this procedure the temperatures of the substrate band 8 and the fluid silicon to be supplied can be kept (virtually) constant. During foil casting a crystallised layer 16 is produced on the surface of the substrate band. The crystallised layer 16 is thicker at the output end of the casting frame. A thicker crystal layer provides greater thermal resistance, which, in turn, ensures a lower crystal growth rate. The rate of crystallisation v thus decreases in a direction perpendicular to the substrate band 8. According to the invention a doping substance is used which has an equilibrium segregation coefficient k₀ that typically is less than 0.01. One example of such a doping substance is gallium, which has an equilibrium segregation coefficient k₀ of approximately 0.008. At a relatively high crystallisation rate v the concentration of gallium in the solid silicon will be virtually the same as the concentration of gallium in the fluid silicon. The gallium doping on the substrate surface is thus virtually the same as the gallium doping in the fluid silicon supplied. If this value is, for example, 2×10¹⁶ atoms per cm⁻³, the gallium doping on the underside of the foil 16, that is to say the side of the substrate band 8, will also be approximately 2×10¹⁶ atoms per cm⁻³. However, because the rate of crystallisation decreases in the direction perpendicular to the substrate band 8, the gallium doping in that direction will also decrease. After all, it follows from equations 2 and 3:

C^{S}_{eff}=C^{L}₀×k₀./(k₀+(1−k₀)exp(−vδ/D)) (4)

and for gallium;

k₀<<1 (5)

For a low rate v it follows from equations 4 and 5 that:

C^{S}_{eff}=C^{L}₀×k₀ (6)

In other words the concentration of gallium will decrease in the crystallised silicon in the direction perpendicular to the substrate band 8. The gradient of this profile is such that the concentration of gallium is appreciably reduced towards the top surface of the silicon foil 16. This is a direct consequence of the very low equilibrium segregation coefficient k₀ of gallium. If, for example, boron (k₀=0.8) were to be used, this principle is barely effective.

Thus a silicon foil 16 has been-produced with a variable p-type doping that generates a drift field in the silicon foil 16. A solar cell produced using a foil 16 produced in this way corresponds to the drift field cells from the state of the art. An example of a doping profile for a foil 16 that has been produced in accordance with the method of the invention is shown in FIG. 2. In FIG. 2 the distance from the surface of the foil 16 can be seen on the X axis and the level of the gallium doping achieved can be seen on the Y axis. In FIG. 2 d=0 corresponds to the top surface of the foil 16 in FIG. 1.

In one embodiment of the invention the silicon foil 16 is then doped with an n-type doping, so that a pn transition in the silicon foil 16 is produced. The additional n-type doping can, for example, be carried out making use of a diffusion process. The silicon foil 16 is then doped with, for example, a thin aluminium layer (p-type) on the underside of the foil 16. As a result a p+ region is produced in the silicon foil 16 in conjunction with metallization on the underside, so that a rear contact with good conductivity is produced. The result of these two additional steps is shown in FIG. 3. In this figure the n-type doping, which in this example has a maximum value of 3×10²⁰, can be seen on the left-hand side. On the right-hand side it can be seen that in this example the p+doping has a maximum value of 3×10¹⁸. As a final step a conducting contact is made on the front, so that the foil 16 can be used as a solar cell that contains an integral drift field. Tests have shown that the efficiency of solar cells that have been made using the method according to the invention is increased by approximately 1%. This is an absolute percentage which in the field of solar cells, where an efficiency is of the order to magnitude of 14%, may be termed appreciable.

In one embodiment of the invention the dissipation of heat to the substrate or to the grating during the growth process is actively influenced by means of heating the substrate or the grating. In FIG. 4 an example is shown where additional halogen lamps 20 are arranged approximately halfway along the casting frame 2 below the substrate band 8. In FIG. 4 the elements that have already been shown in FIG. 1 have the same reference numerals as in FIG. 1. The halogen lamps 20 heat the substrate band 8 so that the temperature of the crystallised silicon 16 is also increased at the location. Mirrors 22 are arranged below the halogen lamps 20 so that the radiation from the halogen lamps 20 is used more effectively. Preferably a thin substrate band 8 is used so that this has a low thermal capacity in order to be able to achieve a rapid reaction time for the process. Because the crystallised silicon 16 is actively heated on the underside, the quantity of heat dissipated will fall where the halogen lamp heats the substrate band 8. The consequence is that the rate of crystallisation falls at that location. The dissipation of heat in the direction of movement of the substrate band 8 can be regulated by suitable arrangement of heating elements, such as the halogen lamps 20.

In one embodiment of the method the process parameters are so chosen that the rate of crystal growth varies during the growth process from approximately 10 mm/sec to approximately 10 μm/sec. Good results are achieved with these values.

It will be understood that on reading the above variants will be immediately apparent to those skilled in the art. Instead of gallium, aluminium, indium or group V elements can also be used. Such variants are considered to fall within the scope of the application as described in appended claims.

1-10. (canceled)

11. A method of producing a crystalline semiconductor foil with an integrated electric field, comprising:
doping a fluid semiconductor with a doping substance having an equilibrium segregation coefficient k₀, where k₀<<1,
drawing a foil from a melting crucible containing said fluid semiconductor in a production direction; and
cooling said fluid semiconductor in such a way that a crystal growth speed varies in a direction essentially perpendicular to the production direction of the foil during crystal growth.

12. The method of claim 11, wherein the crystal growth speed decreases during crystal growth.

13. The method of claim 11, wherein the heat of crystallisation is dissipated so rapidly whereupon the initial crystal growth speed is so high that the effective segregation coefficient k_{eff} is virtually equal to 1.

14. The method of claim 11, wherein the equilibrium segregation coefficient k₀<0.01.

15. The method of claim 11, wherein the fluid semiconductor crystallises upon coming into contact with a substrate or with a grating with a lower temperature than that of the fluid semiconductor.

16. The method of claim 15, wherein dissipation of heat to the substrate or to the grating during the growth process is actively influenced by means of heating the substrate or the grating.

17. The method of claim 15, further including:
filling a casting frame with the fluid semiconductor; and
passing a substrate band underneath the casting frame, wherein the substrate band has a lower temperature than the fluid semiconductor in the bottom of the casting frame whereupon a bottom layer of the fluid semiconductor crystallises on the substrate band and a silicon foil is produced on the substrate band on one side of the casting frame.

18. The method of claim 11, wherein the doping substance is gallium, aluminium, indium or group V elements.

19. The method of claim 11, wherein during crystallisation of the foil the crystal growth speed varies between 10 mm/sec to 10 μm/sec.

20. The method of claim 12, wherein the equilibrium segregation coefficient k₀<0.01.

21. The method of claim 12, wherein the fluid semiconductor crystallises upon coming into contact with a substrate or with a grating with a lower temperature than that of the fluid semiconductor.

22. The method of claim 13, wherein the fluid semiconductor crystallises upon coming into contact with a substrate or with a grating with a lower temperature than that of the fluid semiconductor.

23. The method of claim 21, further including:
filling a casting frame with the fluid semiconductor; and
passing a substrate band underneath the casting frame, wherein the substrate band has a lower temperature than the fluid semiconductor in the bottom of the casting frame whereupon a bottom layer of the fluid semiconductor crystallises on the substrate band and a silicon foil is produced on the substrate band on one side of the casting frame.

24. The method of claim 23, further including:
filling a casting frame with the fluid semiconductor; and
passing a substrate band underneath the casting frame, wherein the substrate band has a lower temperature than the fluid semiconductor in the bottom of the casting frame whereupon a bottom layer of the fluid semiconductor crystallises on the substrate band and a silicon foil is produced on the substrate band on one side of the casting frame.

25. The method of claim 16, further including:
filling a casting frame with the fluid semiconductor; and
passing a substrate band underneath the casting frame, wherein the substrate band has a lower temperature than the fluid semiconductor in the bottom of the casting frame whereupon a bottom layer of the fluid semiconductor crystallises on the substrate band and a silicon foil is produced on the substrate band on one side of the casting frame.

26. The method of claim 24, further including:
filling a casting frame with the fluid semiconductor; and
passing a substrate band underneath the casting frame, wherein the substrate band has a lower temperature than the fluid semiconductor in the bottom of the casting frame whereupon a bottom layer of the fluid semiconductor crystallises on the substrate band and a silicon foil is produced on the substrate band on one side of the casting frame.

27. The method of claim 12, wherein the doping substance is gallium, aluminium, indium or group V elements.

28. The method of claim 13, wherein the doping substance is gallium, aluminium, indium or group V elements.

29. The method of claim 14, wherein the doping substance is gallium, aluminium, indium or group V elements.

30. A crystalline semiconductor foil obtained by the method of claim 11.
